(19) United States
(12) Patent Application Publication
(10) Pub. No.: US 2012/0280227 A1
(43) Pub. Date: Nov. 8, 2012

(54) OXIDE SEMICONDUCTOR DEVICE AND METHOD OF MANUFACTURING THE SAME

(76) Inventors: Hironori Wakana, Tokorozawa (JP); Tetsufumi Kawamura, Kodaira (JP); Hiroyuki Uchiyama, Musashimurayama (JP); Kuniharu Fujii, Kodaira (JP)

(21) Appl. No.: 13/512,062

(22) PCT Filed: Nov. 22, 2010
(86) PCT No.: PCT/JP2010/070816

§ 371 Date: May 25, 2012

(30) Foreign Application Priority Data
Nov. 27, 2009 (JP) 2009-269436

(51) Int. Cl. H01L 29/78; H01L 21/336

(52) U.S. Cl. 257/43; 438/104; 257/E29.255; 257/E21.409

(57) ABSTRACT

Features are forming a gate electrode on an insulating substrate; forming a first semiconducting layer mainly composed of an indium oxide and having a film thickness of 5 nm or more onto the gate electrode interposing a gate insulating film; forming a second semiconducting layer mainly composed of zinc and tin oxides without containing indium and having a film thickness of 5 to 50 nm on the first semiconducting layer, and including a step of forming a source electrode and a drain electrode on the second semiconducting layer. In this manner, by combining the materials of the first semiconducting layer and the second semiconducting layer with each other, a semiconductor device with a reduced dependency on the film thickness of the semiconducting layer, little characteristic variations on a large area substrate is provided.

### TECHNICAL FIELD

The present invention relates to an oxide semiconductor device and more particularly relates to a semiconductor device containing a field effect transistor in which an oxide film is used as a channel.

### BACKGROUND ART

Various studies and developments have been made on a display device having a thin film transistor (TFT) device as a driving transistor for electronic devices. This TFT, which makes it possible to save space, has been used as a transistor for driving a display device of a portable apparatus such as a portable phone, a notebook-type personal computer, a PDA and the like. At present, most of portions of such a TFT have been manufactured by silicon-based semiconductor materials typically represented by crystalline silicon and amorphous silicon. This is because of advantages in that the TFT can be manufactured by using conventional manufacturing processes and manufacturing techniques for a semiconductor device. However, when the semiconductor manufacturing process is used, since the processing temperature is 350° C. or higher, there are some limitations to a substrate to be formed. In particular, most of substrates made of glass or flexible substrates have a heat resistant temperature of 350° C. or lower, and it is consequently difficult to form TFTs by using conventional semiconductor manufacturing processes. For this reason, in recent years, studies and developments have been made on a TFT device (oxide TFT) in which an oxide semiconductor material that can be processed at a low temperature is used. Since the oxide TFT can be manufactured at a low temperature, it is possible to form the oxide TFTs onto a substrate, such as a glass substrate and a plastic substrate, which can be flexibly bendable. Thus, a novel device that has not been conventionally known can be manufactured at low costs. Moreover, by utilizing transparency of the oxide material, application to an RFID tag or the like is also available.

### PRIOR ART DOCUMENTS

### Patent Document

Japanese Patent Application Laid—Open Publication No. 2009-170905

### Non-Patent Document

IEDM Tech. Dig., pp. 73-76, (2008)

### DISCLOSURE OF THE INVENTION

### Problems To Be Solved By the Invention

It has been known that the electric characteristics of the oxide semiconductor TFT are strongly dependent on a channel film thickness. For this reason, it is very difficult to form a TFT array having uniform characteristics onto a large area substrate. At present, solutions of this problem are mostly dependent on the device. Moreover, IEDM Tech. Dig., pp. 73-76, (2008) (Non-Patent Document 1) and Japanese Patent Application Laid—Open Publication No. 2009-170905 (Patent Document 1) report that attempt the characteristic improvements, it is reported that by stacking two or more oxide semiconducting layers, the field-effect mobility is improved by two or more times in comparison with that of a single layer structure. However, as the film thickness of a lower channel layer increases, the threshold voltage and field-effect mobility greatly vary. In this method also, the thickness of the channel layer strongly influences the TFT characteristics. For this reason, when a large number of TFTs are formed on a large area without controlling the channel film thickness in the conventional technique, variations in the TFT characteristics increase, causing a problem of an extreme reduction in the yield of products.

A preferred aim of the present invention is to reduce the influences of the channel film thickness that cause variations in the TFT characteristics. The above and other preferred aims and novel characteristics of the present invention will be apparent from the description of the present specification and the accompanying drawings.

### Means For Solving the Problems

The typical ones of the inventions disclosed in the present application will be briefly described as follows.

First, the present invention is characterized in that a field-effect transistor includes: a gate electrode, a first semiconducting layer that is formed on the gate electrode interposing a gate insulating layer therebetween; a second semiconducting layer connected to the first semiconducting layer; a source electrode connected to the second semiconducting layer; and a drain electrode connected to the second semiconducting layer, and this structure is characterized in that the first semiconducting layer contains In element and O element, and the second semiconducting layer contains Zn element and O element.

Second, in a method of manufacturing a field-effect transistor, a first process for forming a first semiconducting layer containing In element and O element and a second process for forming a second semiconducting layer containing Zn element and O element on the first semiconducting layer are included.

### Effects of the Invention

The present invention makes it possible to reduce the film-thickness dependence of a field-effect transistor.

BRIEF DESCRIPTIONS OF THE DRAWINGS

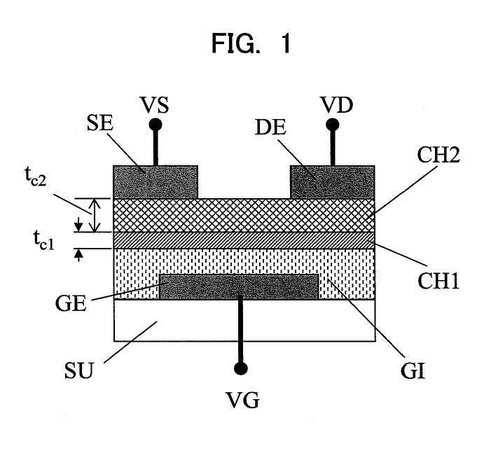

FIG. 1 is a cross-sectional view illustrating a structure of a semiconductor device according to a first example of the present invention;

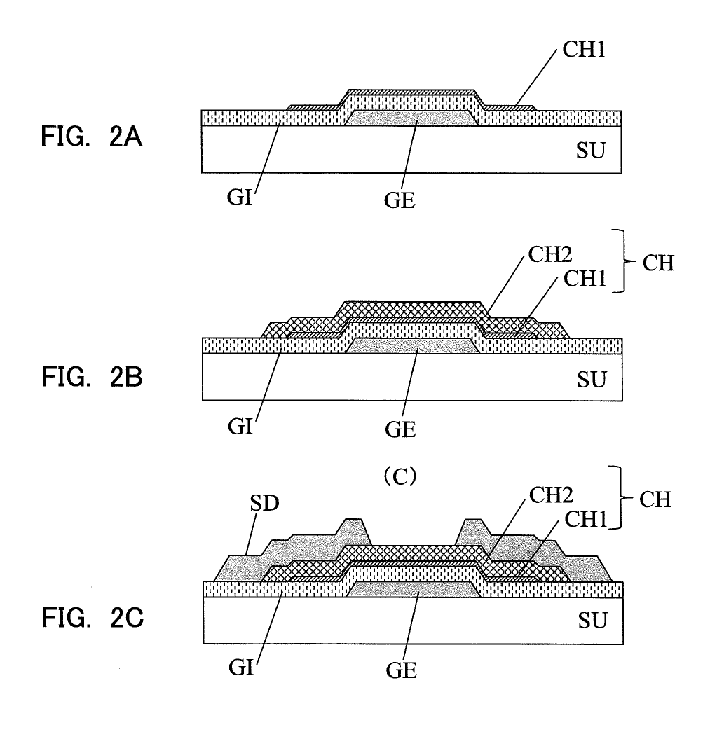

FIGS. 2A to 2C are cross-sectional views illustrating a structure of a semiconductor device and a manufacturing method of the same according to a second example of the present invention;

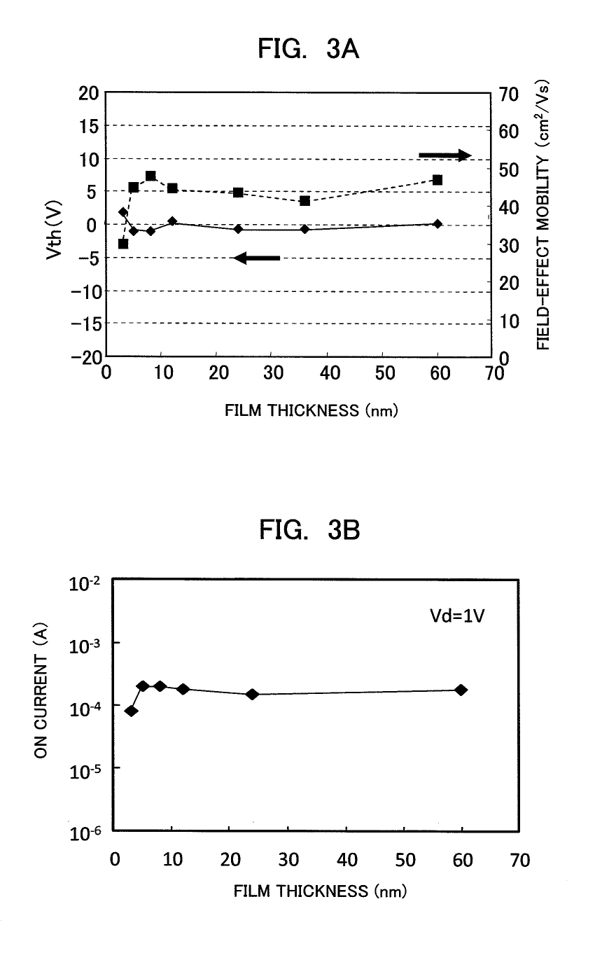

FIGS. 3A and 3B are graphs illustrating relationships among a film thickness, a threshold voltage, a field-effect mobility and an ON-state current of a first semiconducting layer in the semiconductor device formed in the second example of the present invention;

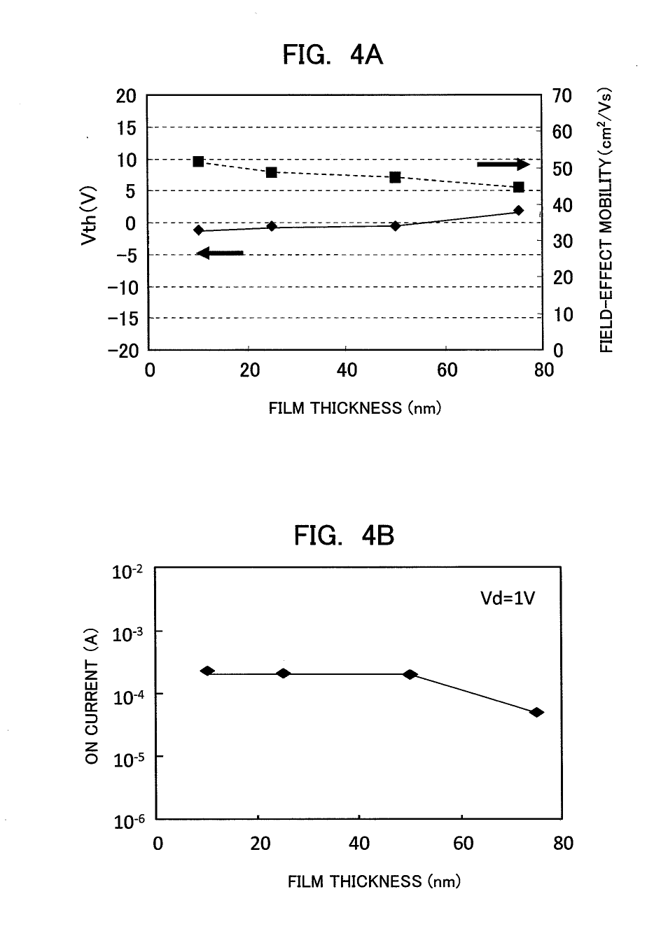

FIGS. 4A and 4B are graphs illustrating relationships among a film thickness, a threshold voltage, a field-effect mobility and an ON-state current of a second semiconducting layer in the semiconductor device formed in the second example of the present invention;

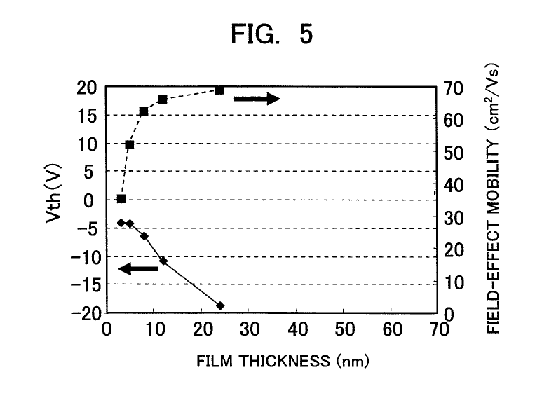

FIG. 5 is a graph illustrating relationships among a film thickness, a threshold voltage and a field-effect mobility of a first semiconducting layer in a semiconductor device formed in a comparative example 1 of the present invention;

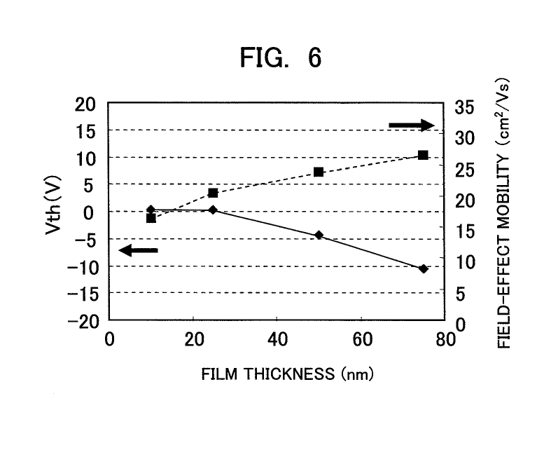

FIG. 6 is a graph illustrating relationships among a film thickness, a threshold voltage and a field-effect mobility of a semiconducting layer in a semiconductor device formed in a comparative example 1 of the present invention;

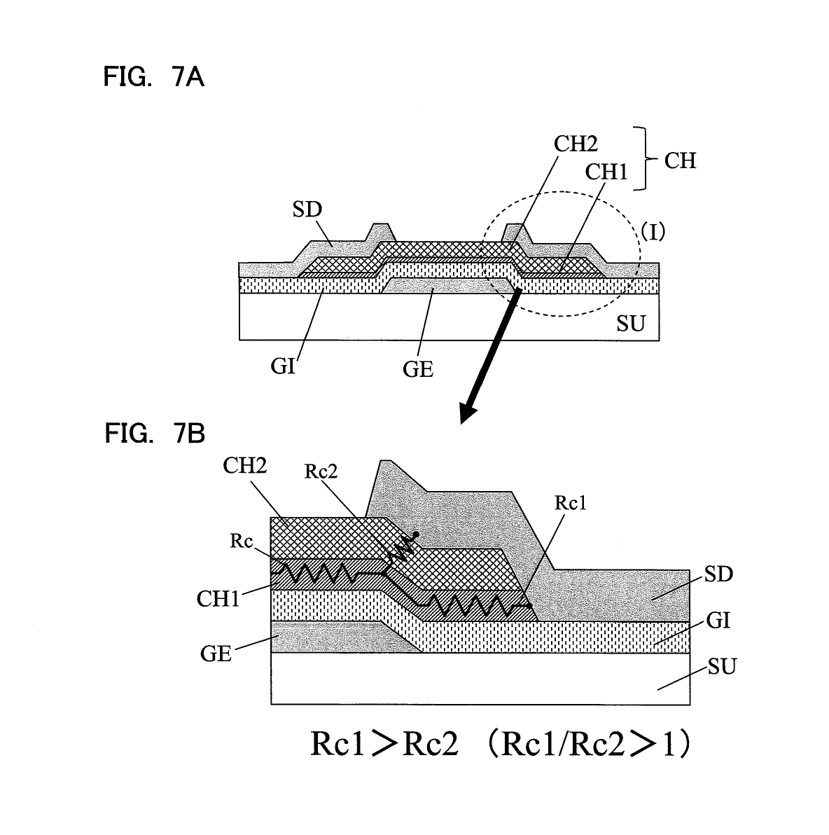

FIGS. 7A and 7B are cross-sectional views illustrating a structure of a semiconductor device according to a third example of the present invention;

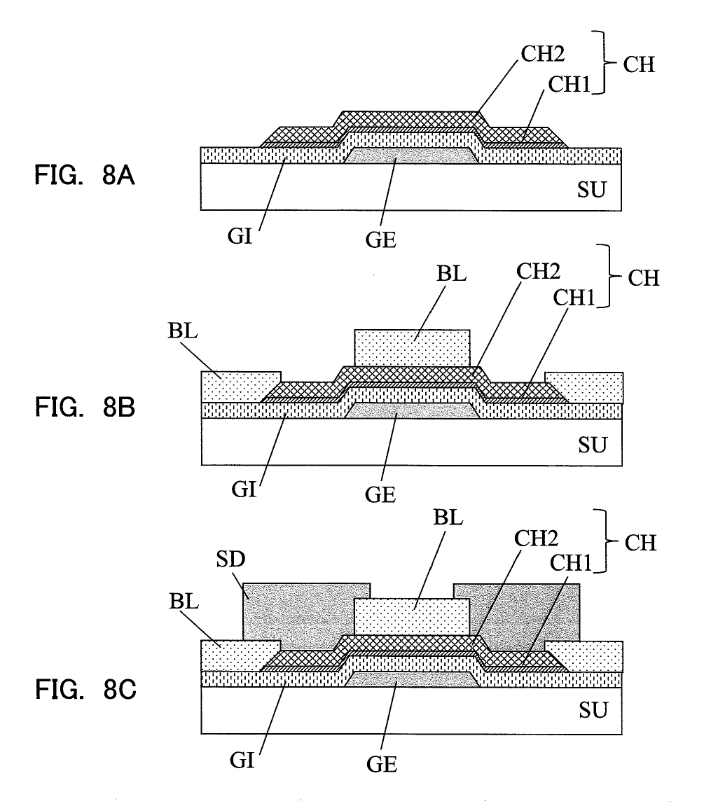

FIGS. 8A to 8C are cross-sectional views illustrating a structure of a semiconductor device and a manufacturing method of the same according to a fourth example of the present invention;

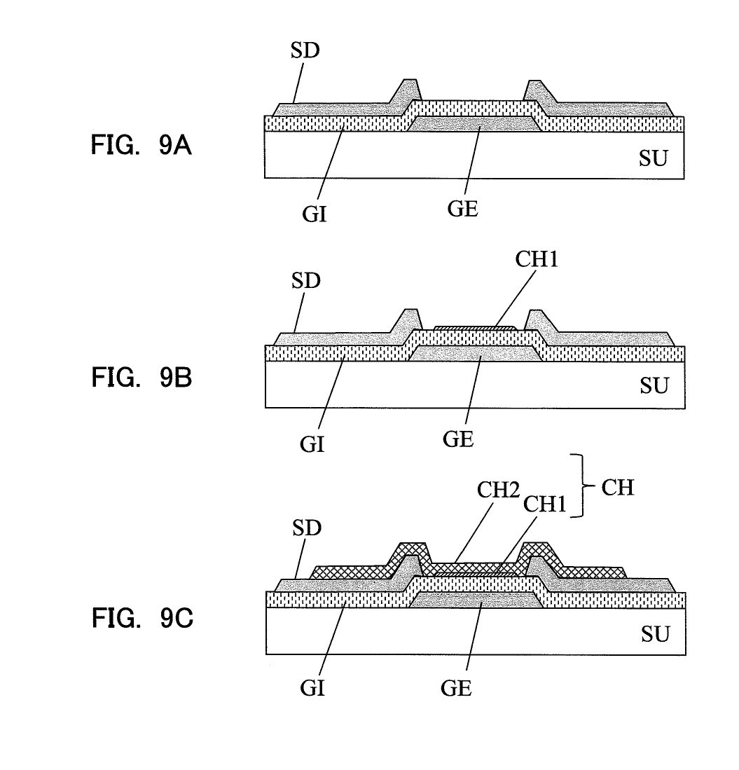

FIGS. 9A to 9C are cross-sectional views illustrating a structure of a semiconductor device and a manufacturing method of the same according to a fifth example of the present invention;

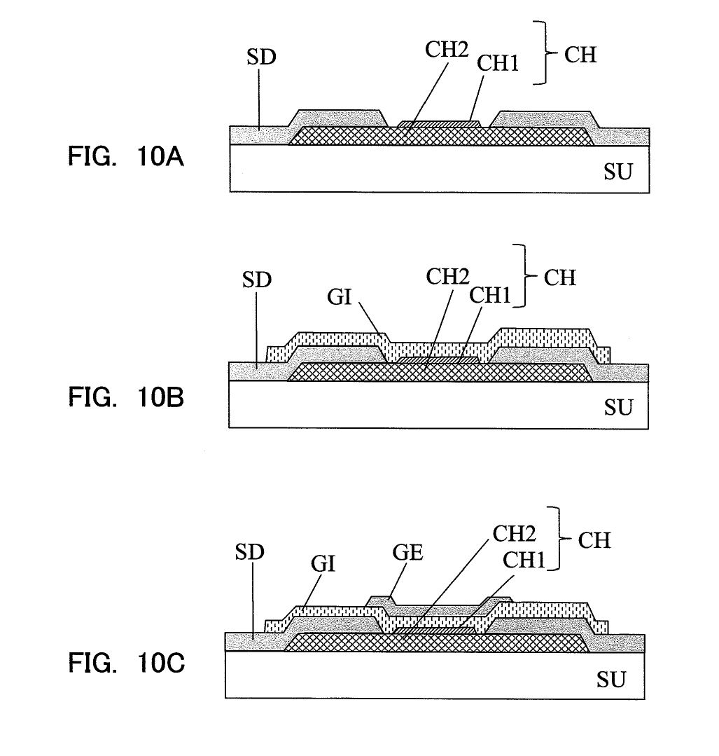

FIGS. 10A to 10C are cross-sectional views illustrating a structure of a semiconductor device and a manufacturing method of the same according to a sixth example of the present invention;

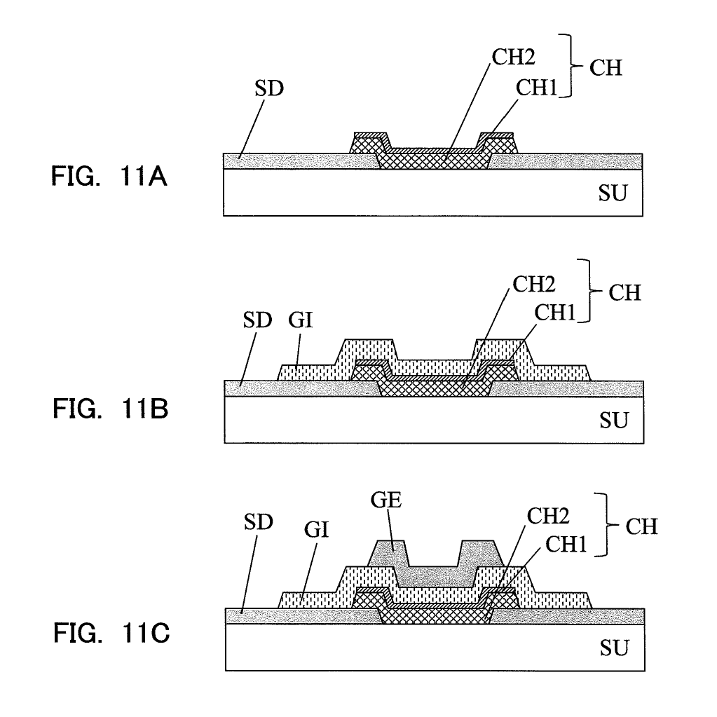

FIGS. 11A to 11B are cross-sectional views illustrating a structure of a semiconductor device and a manufacturing method of the same according to a seventh example of the present invention;

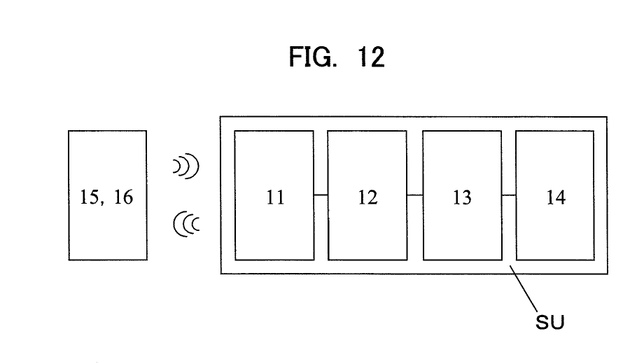

FIG. 12 is a block diagram illustrating a structure of an RFID (wireless tag) according to an eighth example of the present invention;

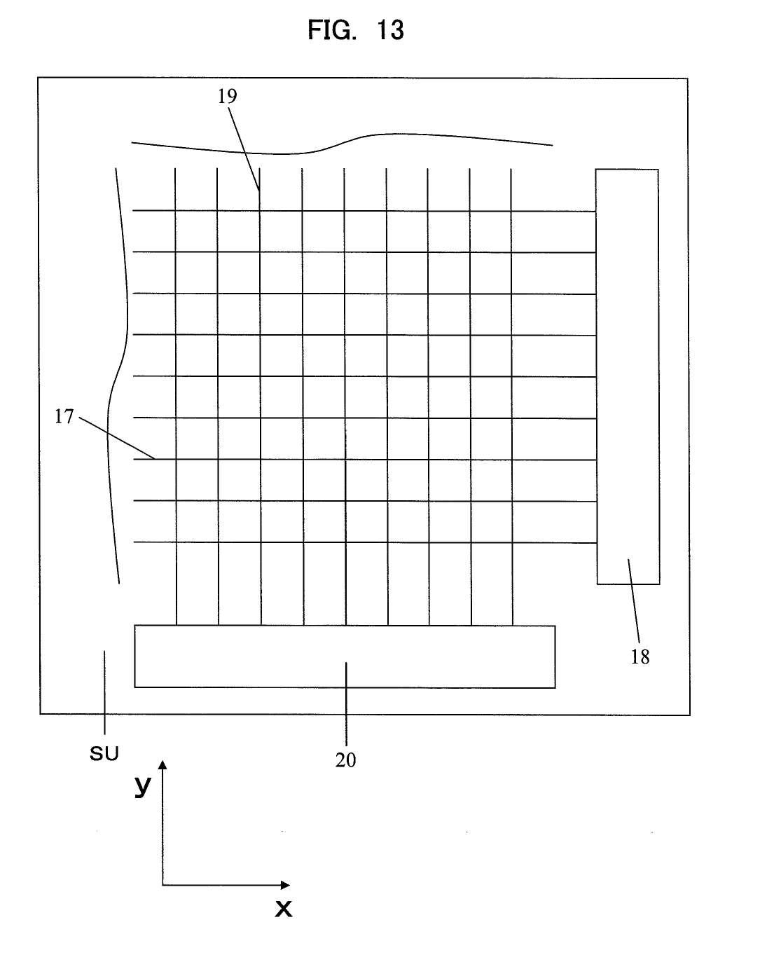

FIG. 13 is a schematic diagram illustrating a structure of a semiconductor device according to a ninth example of the present invention; and

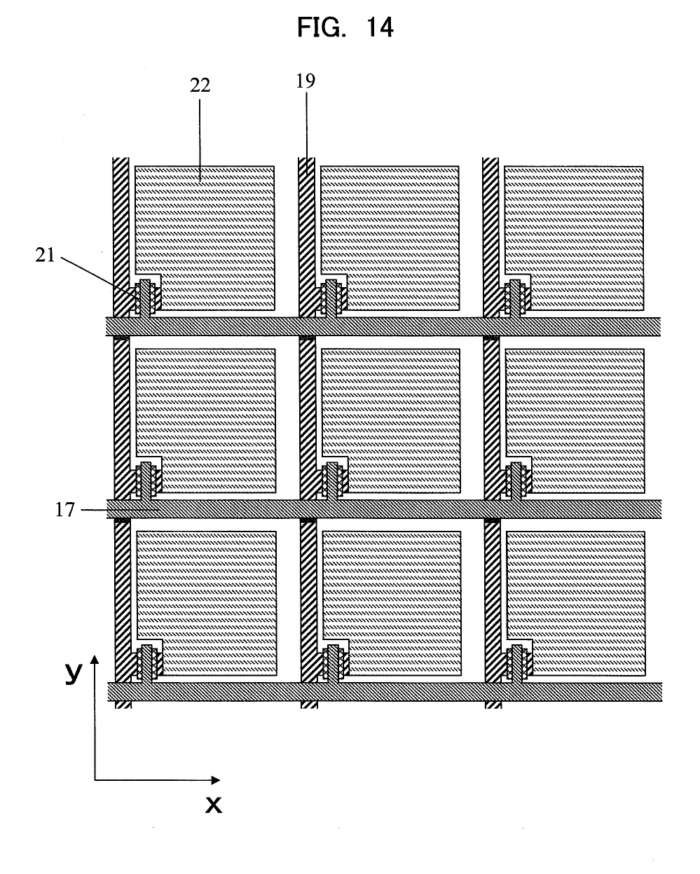

FIG. 14 is a schematic diagram illustrating a structure in which a semiconductor device according to a tenth example of the present invention is used in an active matrix-type liquid crystal display.

### BEST MODE FOR CARRYING OUT THE INVENTION

### First Example

First, a schematic device structure of the present invention is described in a first example. A method of manufacturing a semiconductor device shown in FIG. 1 includes the steps of: forming a gate electrode GE on a substrate SU; forming a first semiconducting layer CH1 mainly composed of an indium oxide having a film thickness (tc1) of 5 nm or more onto the gate electrode GE interposing a gate insulating film GI between the first semiconducting layer CH1 and the gate electrode GE; forming a second semiconducting layer CH2 mainly composed of zinc and a tin oxide with a film thickness (tc2) of 5 to 50 nm onto the first semiconducting layer CH1; and forming a source electrode SE and a drain electrode DE onto the second semiconducting layer CH2. In FIG. 1, VS, VD and VG respectively indicate a source voltage, a drain voltage, and a gate voltage. By combining the first semiconducting layer CH1 and the second semiconducting layer CH2 in this manner, a semiconductor device in which the threshold voltage and field-effect mobility of the TFT have a reduced dependency on the film thickness of the semiconducting layer can be provided. Moreover, the semiconductor device obtained by a typical embodiment is a semiconductor device manufactured by the above-described manufacturing method.

Examples of the substrate include a Si substrate, a sapphire substrate, a quartz substrate and a glass substrate, as well as a flexible resin sheet, a so-called plastic film, etc. Examples of the plastic film include polyethylene terephthalate, polyethylene naphthalate, polyetherimide, polyacrylate, polyimide, polycarbonate, cellulose triacetate, cellulose acetate propionate, etc. Examples of the electrode material include: oxide materials in which Al, Ga, In, B or the like is added to ITO or ZnO, and metals, such as Mo, Co, W, Ti, Au, Al, Ni, Pt or the like and composite materials thereof. Moreover, these semiconductor materials may be subjected to a doping treatment, if necessary. The first channel layer is a compound containing at least In element and O element.

Furthermore, compounds containing Zn element, Sn element, Ge element or Si element may be used. Specific examples of the compounds include indium oxide, In—Mn—O (Mn:Sn, Zn, Si, Ge) in which tin, zinc, silicon and germanium are added to indium oxide, etc. In this case, in the constituent elements other than oxygen, the composition ratio of In element is 50% or more. The second channel layer is a compound containing at least Zn element and O element. This may further contain a Sn element. Specific examples of the compound correspond to Zn—O, Zn—Sn—O, etc., without containing In element. In order to improve performances of the oxide semiconductor transistor, after being formed, the oxide semiconductor may be subjected to an annealing treatment. Examples of the insulating film material, oxides and nitrides of silicon, oxides and nitrides of aluminum, and metal oxides, such as Y₂O₃, YSZ and HfO₂, as well as organic insulating polymers, such as a polyimide derivative, a benzocyclobutene derivative, a photoacrylic derivative, a polystyrene derivative, a polyvinyl phenol derivative, a polyester derivative, a polycarbonate derivative, a polyester derivative, a polyvinyl acetate derivative, a polyurethane derivative, a polysulfone derivative, an acrylate resin, an acryl resin, an epoxy resin, etc.

As described above, the invention according to the present example provides an field-effect transistor, and a feature is a structure including: a gate electrode; a first semiconducting layer formed on the gate electrode interposing a gate insulating film between the first semiconducting layer and the gate electrode; a second semiconducting layer connected to the first semiconducting layer; a source electrode connected to the second semiconducting layer; and a drain electrode connected to the second semiconducting layer, the first semiconducting layer containing In element and O element, and the second semiconducting layer containing Zn element and O element. By using this structure, it is possible to reduce the film-thickness dependency of the field-effect transistor. More specifically, it is possible to reduce the film-thickness dependency of the threshold voltage and field-effect mobility on the semiconducting layer. As a result, it is possible to provide a TFT array having uniform characteristics on a large area substrate, and consequently, it is possible to achieve a display device, an RFID tag, etc. using these TFTs.

The basis of the film-thickness dependency will be explained later based upon experimental results, etc.

Note that, the invention according to the present example is not limited to the above-mentioned structure, and various changes may be made within the scope not departing from the technical idea of the present invention.

### Second Example

FIG. 2 is a diagram illustrating a structure and a manufacturing method of a semiconductor device in accordance with a second example. As the semiconductor device, a so-called bottom-gate/top-contact type oxide TFT is used. The “bottom-gate” mentioned here refers to a structure in which a gate electrode GE is formed on a layer lower than a semiconducting layer CH, and the “top-contact” refers to a structure in which a source-drain electrode SD is formed on a layer upper than the semiconducting layer CH.

A manufacturing method of the semiconductor device according to the second example will be described below. First, as shown in FIG. 2A, a gate electrode GE, a gate insulating film GI and a first semiconducting layer CH1 are formed on an insulator substrate SU.

The substrate SUB is made of, for example, a glass, quartz or plastic film, and, if necessary, a coating process of an insulating film is carried out on a surface on the side where the gate electrode GE is formed.

The gate electrode GE is prepared as a single film made of a conductive material, such as molybdenum, chromium, tungsten, aluminum, copper, titanium, nickel, tantalum, silver, cobalt, zinc, gold or other metals, or an alloy film of these, a laminate film of these, or a metal oxide conductive film, such as ITO (In—Sn—O: indium-tin oxide), a laminate film of these and metal, or a metal nitride conductive film, such as titanium nitride (Ti—N), a laminate film of these and metal, other conductive metal compound films, a laminate film of these and metal, a semiconductor having carriers at a high density, or a laminate film of the semiconductor and metal, and its film-forming process is carried out by a vapor deposition method, a chemical vapor deposition (CVD) method, a sputtering method, or the like, and the film is processed by using a combination of a general-use photolithography technique and dry etching or wet etching.

The gate insulating film GI is preferably prepared as an oxide insulating film made of Si—O, Al—O, etc, or may be prepared as an inorganic insulating film formed of a material other than oxides, such as Si—N, or as an organic insulating film formed of perylene, etc. The film-forming process of the gate insulating film GI is carried out by a vapor deposition method, a CVD method, a sputtering method, an application method, or the like, and the film is processed by using a combination of a general-use photolithography technique and dry etching or wet etching.

The first semiconducting layer CH1 is formed of an oxide, such as In—O, In—Zn—O, In—Sn—O, In—Ga—O or In—Si—O and a composite oxide thereof, and its film-forming process is carried out by a sputtering method, a pulsed laser deposition (PLD) method, a CVD method, an application method, a printing process, etc. After completion of the step of forming the first semiconducting layer CH1, a step of removing the first semiconducting layer CH1 except for a predetermined portion is carried out. This step is carried out by using a combination of a general-use photolithography technique and wet etching or dry etching. In the present example, as the first semiconducting layer CH1, In—Sn—O (In:Sn=90:10) is formed with a film thickness of 3 to 60 nm, by a sputtering method, under conditions of a gas pressure of 0.5 Pa (Ar+10% O₂), a DC power of 50 W and a growth temperature (room temperature). After completion of this step, the first semiconducting layer CH1 is processed into an island pattern. In this case, it is defined that the “island pattern” refers to a state in which required portions of the first semiconducting layer CH1 are left and the other portion are removed. This term is also used in the same manner in the following descriptions.

Thereafter, as shown in FIG. 2B, a step of forming the second semiconducting layer CH2, and a step of removing the second semiconducting layer CH2 except for a predetermined portion is carried out. After completion of this step, the second semiconducting layer CH2 is processed into an island pattern so as to completely cover the first semiconducting layer CH1. In this case, the term “completely cover” means that not only the upper portion of the first semiconducting layer, but also the side portions thereof are covered with the second semiconducting layer, with a source electrode or a drain electrode to be formed later being not directly connected to the first semiconducting layer. In the above-mentioned step of forming the second semiconducting layer, the second semiconducting layer CH2 is formed of an oxide, such as Zn—Sn—O, Zn—O, Sn—O or the like, and its film-forming process can be carried out by a sputtering method, a PLD method, a CVD method, an application method, a printing process, or the like. The step of removing the second semiconducting layer CH2 except for a predetermined portion is carried out by using a combination of a general-use photolithography technique and wet etching or dry etching. In the present example, as the second semiconducting layer CH2, Zn—Sn—O (Zn:Sn=50:50) is formed with a film thickness of 5 to 75 nm, by a sputtering method, under conditions of a gas pressure of 0.5 Pa (Ar+20% O₂), an RF power of 50 W and a growth temperature (room temperature).

Thereafter, as shown in FIG. 2C, a source-drain electrode SD is formed. In the same manner as the gate electrode GE, the source-drain electrode SD is prepared as a single film formed of a conductive material such as, for example, molybdenum, chromium, tungsten, aluminum, copper, titanium, nickel, tantalum, silver, zinc, cobalt, nickel, gold or other metals, or an alloy film of these, a laminate film of these, or a metal oxide conductive film, such as ITO (In—Sn—O: indium-tin oxide), a laminate film of these and metal, or a metal nitride conductive film, such as titanium nitride (Ti—N), a laminate film of these and metal, other conductive metal compound films, a laminate film of these and metal, a semiconductor having carriers at a high density, or a laminate film of the semiconductor and metal, and its film-forming process is carried out by a CVD method, a sputtering method, or the like, and the film is processed by using a combination of a general-use photolithography technique and dry etching or wet etching. A TFT, thus formed, had a channel length of 0.1 mm and a channel width of 2 mm.

Characteristics of the above-described field-effect transistor and the manufacturing method thereof will be described as follows.

The method is characterized by a first step of forming a first semiconducting layer having In element and O element on a gate insulating film and a second step of forming a second semiconducting layer having Zn element and O element on the first semiconducting film. Providing at least these steps is to achieve a preferred aim of the present invention to achieve the field-effect transistor explained with reference to FIG. 1 and to reduce the film-thickness dependency of the field-effect transistor. After the second step, a fourth step of removing the second semiconducting layer except for a predetermined portion is further carried out.

In particular, the invention according to the second example is characterized in that, after carrying out the first step, a third step of removing the first semiconducting layer except for a predetermined portion is further carried out. In particular, these characteristics make it possible to achieve a field-effect transistor having a structure as shown in FIGS. 2A to 2C. The field-effect transistor manufactured by this manufacturing method is particularly characterized in that the first semiconducting layer and the source electrode are not directly connected to each other. The same is true for the relationship between the first semiconducting layer and the drain electrode.

The effects obtained by this structure are clearly indicated in comparison with a field-effect transistor according to FIG. 7 to be described later. That is, the effect for reducing the film-thickness dependency of a field-effect transistor can be achieved without satisfying a relational expression Rc1>Rc2 to be described later.

FIGS. 3A and 3B are relationship diagrams illustrating relationships among a threshold voltage Vth, a field-effect mobility (FIG. 3A) and an ON-state current (FIG. 3B) at the time of applying a drain voltage VD of 1 V and a gate voltage VG of 10V of an oxide TFT manufactured according to the second example, and a film thickness of the first semiconducting layer CH1. Here, the film thickness of the second semiconducting layer CH2 was set to 25 nm. As shown in FIGS. 3A and 3B, when the film thickness of the first semiconducting layer CH1 is 5 nm or more, the threshold voltage was set within a range of ±1 V of the threshold voltage, a field-effect mobility was in a range from 43 to 48 cm²/Vs, and an ON-state current of 2×10⁻⁴ A was exerted. Since changes in characteristics hardly occur relative to the film thickness variations, a TFT array can be easily formed on a large area substrate.

FIGS. 4A and 4B is a relationship diagram illustrating relationships among a threshold voltage Vth, a field-effect mobility (FIG. 4A) and an ON-state current (FIG. 4B) at the time of applying a drain voltage VD of 1 V and a gate voltage VG of 10V of an oxide TFT manufactured in second example, and a film thickness of the second semiconducting layer CH2. Here, the film thickness of the first semiconducting layer CH1 was set to 5 nm. As shown in FIGS. 4A and 4B, when the film thickness of the second semiconducting layer CH2 is 50 nm or less, the threshold voltage was set within a range of ±1 V of the threshold voltage, a field-effect mobility was in a range from 45 to 50 cm²/Vs, and an ON-state current of 2×10⁻⁴ A was exerted. Since changes in characteristics hardly occur relative to the film thickness variations, a TFT array can be easily formed on a large area substrate.

### Comparative Example 1

A comparative example 1 only differs from the second example in that the second semiconducting layer CH2 is formed of an oxide material containing In, and the other points are the same as those of the second example.

The second semiconducting layer CH2 in the comparative example 1 is formed of an oxide, such as In—O, In—Ga—Zn—O, In—Sn—O, In—Zn—O and In—Ga—O, and a composite oxide thereof, and its film-forming process is carried out by a sputtering method, a PLD method, a CVD method, an application method, a printing process, etc. In the present comparative example 1, In—Sn—O was used as the first semiconducting layer CH1 and In—Ga—Zn—O was used as the second semiconducting layer, and the In—Ga—Zn—O film was formed by a sputtering method carried out under the conditions of a gas pressure of 0.5 Pa (Ar+20% O₂), an RF power of 50 W and a growth temperature (room temperature).

FIG. 5 is a relationship diagram illustrating relationships among a threshold voltage Vth and a field-effect mobility relative to a film thickness of a first semiconducting layer CH1 of an oxide TFT manufactured according to the comparative example 1. At this time, the film thickness of the second semiconducting layer CH2 was set to 25 nm. As shown in FIG. 5, as the film thickness of the first semiconducting layer CH1 increased, the threshold voltage was shifted toward the negative side so that the field-effect mobility increased. In comparison with the second example, the dependency on the film thickness of the semiconducting layer was exerted, and this structure was inferior from the viewpoint of variations in the TFT characteristics. The reason for this is explained as follows: It is presumed that, since In was contained in the second semiconducting layer CH2, a carrier network was formed by 5 s electrons of In from the second semiconducting layer CH2 to the first semiconducting layer CH1 so that the number of apparent carriers was increased inside the first semiconducting layer CH1.

In this manner, different from the invention according to the comparative example 1, in particular, since the present applied invention allows the first semiconducting layer CH1 to contain In element, the resulting effect of reducing the film-thickness dependency of a field-effect transistor is achieved.

### Comparative Example 2

A comparative example 2 only differs from the second example in that the two kinds of second semiconducting layers are not used and only a semiconducting layer with a single layer being used, and the other points are the same as those of first example.

The semiconducting layer CH of the present comparative example 2 is formed in an island pattern so as to isolate devices, and the layer is processed by using a combination of a general-use photolithography technique and wet etching or dry etching.

The semiconducting layer CH is formed of an oxide of Zn, In, Ga and Sn, such as Zn—O, In—O, Ga—O, Sn—O, In—Ga—Zn—O, Zn—Sn—O, In—Sn—O, In—Zn—O, Ga—Zn—O and In—Ga—O, and a composite oxide thereof, and its film-forming process is carried out by a sputtering method, a PLD method, a CVD method, an application method, a printing process, etc. In the present comparative example, by using Zn—Sn—O as a semiconducting layer CH, the layer was formed with a thickness of 5 to 60 nm by a sputtering method carried out under the conditions of a gas pressure of 0.5 Pa (Ar+8% O₂), an RF power of 50 W and a growth temperature (room temperature).

FIG. 6 is a relationship diagram illustrating relationships between a threshold voltage Vth and field-effect mobility relative to a film thickness of an oxide TFT manufactured according to the comparative example 2. As shown in FIG. 6, as the film thickness of the semiconducting layer increased, the threshold voltage was shifted toward the negative side so that the field-effect mobility slightly increased. In comparison with the first example, a strong dependency on the film thickness was exerted. The same result was also observed in the other materials, and the reason for this is presumably the number of carriers increased due to an increase of the film thickness.

In this manner, being different from the invention according to the comparative example 2, in particular, since the present invention has a structure in which a two-layer structure of the first semiconducting layer and the second semiconducting layer is combined with a channel material, the resulting effect of reducing the film-thickness dependency of a field-effect transistor is achieved.

### Third Example

A third example differs from the second example in that a step of simultaneously processing the first semiconducting layer CH1 and the second semiconducting layer CH2 is prepared and in that the source-drain electrode wiring layer SD is connected to both of the semiconducting layers CH. The other points are the same as those of the second example.

FIGS. 7A and 7B are diagrams illustrating a structure of a semiconductor device in the present third example. The structure shown in FIG. 7A is manufactured by the following sequence of processes. After the formation of the gate electrode GE and the gate insulating film GI, the first semiconducting layer CH1 and the second semiconducting layer CH2 are sequentially deposited, and the semiconducting layers CH are formed in an island pattern so as to isolate devices by using a combination of a general-use photolithography technique and wet etching or dry etching. The first semiconducting layer CH1 is formed of an oxide, such as In—O, In—Zn—O, In—Sn—O, In—Ga—O and In—Si—O, and a composite oxide thereof, and the second semiconducting layer CH2 is made from an oxide, such as Zn—Sn—O, Zn—O and Sn—O. The film-forming process of these is carried out by a sputtering method, a PLD method, a CVD method, an application method, a printing process, etc. In the present example, by using In—Sn—O (In:Sn=80:20) as the first semiconducting layer CH1, the layer was formed with a thickness of 3 to 60 nm by a sputtering method carried out under the conditions of a gas pressure of 0.5 Pa (Ar+10% O₂), a DC power of 50 W and a growth temperature (room temperature). By using Zn—Sn—O (Zn:Sn=70:30) as the second semiconducting layer CH2, the layer was formed with a thickness of 5 to 75 nm by a sputtering method carried out under the conditions of a gas pressure of 0.5 Pa (Ar+20% O₂), an RF power of 50 W and a growth temperature (room temperature). Thereafter, a source-drain electrode SD is deposited, and the pattern is formed by using a combination of a general-use photolithography technique and dry etching or wet etching.

FIG. 7B shows an enlarged view of an area (I). As shown in FIG. 7B, a resistance value of a channel portion is represented by Rc, a resistance value from the channel portion to the source-drain electrode SD through the first semiconducting layer CH1 is represented by Rc1, and a resistance value from the channel portion to the source-drain electrode SD through the second semiconducting layer CH2 is represented by Rc2. In this case, the “channel layer” refers in particular to a layer provided between the source electrode and the drain electrode of the first semiconducting layer CH1. In the case when Rc1≦Rc2, the threshold voltage of the manufactured TFT was shifted toward the negative side as the film thickness of the semiconducting layer increased. In the case when Rc1>Rc2, the manufactured TFT exerted the same characteristics as those of the manufactured TFT according to the second example, showing a range of the threshold voltage within ±1 V of the threshold voltage, field-effect mobility of 43 to 50 cm²/Vs and an ON-state current of 2×10⁻⁴ A. Based upon these results, it is presumed that, when the source-drain electrode SD is directly connected to the first semiconducting layer CH1 and the second semiconducting layer CH2, the relation of Rc1>Rc2 is indispensably required and that when the resistance value of the first semiconducting layer CH1 is lower than that of the second semiconducting layer CH2, it is the first semiconducting layer CH1 that effectively functions as the channel. In the manufacturing method of the present example, it becomes possible to simultaneously process the CH1 and CH2, and cost reduction is expected by a reduction of the number of processes and photomasks.

### Fourth Example

FIGS. 8A to 8C are diagrams illustrating a structure and a manufacturing method of a semiconductor device in accordance with a fourth example. As the semiconductor device, a so-called bottom-gate/top-contact type oxide TFT is used. The “bottom-gate” mentioned here refers to a structure in which a gate electrode GE is formed on a layer lower than a semiconducting layer CH, and the “top-contact” refers to a structure in which a source-drain electrode SD is formed on a layer upper than the semiconducting layer CH. Except for the manufacturing method, the same materials and processes as those of the second example were used.

The manufacturing method of the semiconductor device according to the present fourth example is as follows. First, as shown in FIG. 8A, a gate electrode GE, a gate insulating film GI, a first semiconducting layer CH1 and a second semiconducting layer CH2 are formed on an insulator substrate SU in this order.

The first semiconducting layer CH1 is formed of an oxide, such as In—O, In—Zn—O, In—Sn—O, In—Ga—O and In—Si—O, and a composite oxide thereof, and the second semiconducting layer CH2 is formed of an oxide such as Zn—Sn—O, Zn—O, and Sn—O. The film-forming process of these is carried out by a sputtering method, a PLD method, a CVD method, an application method, a printing process, etc. In the present example, as the first semiconducting layer CH1, In—Sn—O (In:Sn=70:30) i s formed with a film thickness of 3 to 60 nm, by a sputtering method, under conditions of a gas pressure of 0.5 Pa (Ar+10% O₂), a DC power of 50 W and a growth temperature (room temperature). As the second semiconducting layer CH2, Zn—Sn—O (Zn:Sn=30:70) is formed with a film thickness of 5 to 75 nm, by a sputtering method, under conditions of a gas pressure of 0.5 Pa (Ar+20% O₂), an RF power of 50 W and a growth temperature (room temperature). After completion of the steps of sequentially depositing the first semiconducting layer CH1 and the second semiconducting layer CH2 in this manner, a step of removing the first semiconducting layer CH1 and the second semiconducting layer except for predetermined portions is carried out. The processing of this step is carried out by using a combination of a general-use photolithography technique and dry etching or wet etching.

Thereafter, as shown in FIG. 8B, a barrier layer BL is deposited and processed so that a wiring contact hole CON in association with the second semiconducting layer CH2 is formed. As the barrier layer BL, an oxide insulating film such as Si—O, Al—O or the like is used, and an inorganic insulating film other than the oxide, such as Si—N, or an organic insulating film, such as parylene or the like, may also be used. The film-forming process of the barrier layer BL is carried out by a CVD method, a sputtering method, an application method, or the like. The film is processed by using a combination of a general-use photolithography technique and dry etching or wet etching.

Thereafter, as shown in FIG. 8C, a source-drain electrode SD is deposited, and the film is processed by using a combination of a general-use photolithography technique and dry etching or wet etching.

A TFT manufactured with a channel length of 0.1 mm and a channel width of 2 mm had the same characteristics as those of the TFT manufactured according to the second example. Within a range of 5 nm or more in the film thickness of the first semiconducting layer CH1 and a range of 5 to 50 nm in the film thickness of the second semiconducting layer CH2, a threshold voltage within ±1 V, a field-effect mobility in a range from 45 to 51 cm²/Vs and an ON-state current of 2×10⁻⁴ A were obtained. Since changes in characteristics relative to film-thickness variations hardly occurred, it is possible to easily manufacture a TFT array on a large area substrate.

The above-mentioned field-effect transistor and the features of the manufacturing method thereof will be discussed below in comparison with, in particular, the field-effect transistor according to the second example and the manufacturing method thereof.

The invention according to fourth example is characterized in that, after completion of a first step of forming a first semiconducting layer containing In element and O element on a gate insulating film, a second step of forming a second semiconducting layer containing Zn element and O element on the first semiconducting layer is carried out, and after completion of the second step, a sixth step of removing the first semiconducting layer and the second semiconducting layer except for predetermined portions is further carried out.

The field-effect transistor manufactured in this manufacturing method makes it possible to achieve the effect for reducing the film-thickness dependency of a field-effect transistor in the same manner as the second example, in particular, by the structure in which only the source electrode and the second semiconducting layer are directly connected with each other.

### Fifth Example

FIGS. 9A to 9C is a view illustrating a structure and a manufacturing method of a semiconductor device in accordance with the present fifth example. As the semiconductor device, a so-called bottom-gate/bottom-contact type oxide TFT is used. The “bottom-gate” mentioned here refers to a structure in which a gate electrode GE is formed on a layer lower than a semiconducting layer CH, and the “bottom-contact” refers to a structure in which a source-drain electrode SD is formed on a layer lower than the semiconducting layer CH. Except for the manufacturing method, the same materials and processes as those of the second example were used.

The manufacturing method of the semiconductor device according to the present fifth example is as follows. First, as shown in FIG. 9A, a gate electrode GE, a gate insulating film GI and a source-drain electrode SD are formed on an insulator substrate

SU in this order.

Thereafter, as shown in FIG. 9B, a first semiconducting layer CH1 is formed. The first semiconducting layer CH1 is made from an oxide, such as In—O, In—Zn—O, In—Sn—O, In—Ga—O and In—Si—O, and a composite oxide thereof, and its film-forming process is carried out by a sputtering method, a PLD method, a CVD method, an application method, a printing process, etc. The film is processed by using a combination of a general-use photolithography technique and dry etching or wet etching. At this time, with respect to the order of forming the source-drain electrode SD and the first semiconducting layer CH1, either may be carried out first, with the other being carried out second. In the present example, as the first semiconducting layer CH1, In—O (100% indium oxide) was formed with a film thickness of 3 to 60 nm by a sputtering method carried out under the conditions of a gas pressure of 0.5 Pa (Ar+10% O₂), a DC power of 50 W and a growth temperature (room temperature).

Thereafter, as shown in FIG. 9C, a second semiconducting layer CH2 is formed. The second semiconducting layer CH2 is made from an oxide, such as Zn—Sn—O, Zn—O and Sn—O, and its film-forming process is carried out by a sputtering method, a PLD method, a CVD method, an application method, a printing process, etc. The film is processed by using a combination of a general-use photolithography technique and dry etching or wet etching. As the second semiconducting layer CH2, Zn—Sn—O (Zn:Sn=80:20) was formed with a film thickness of 5 to 75 nm, by a sputtering method carried out under the conditions of a gas pressure of 0.5 Pa (Ar+20% O₂), an RF power of 50 W and a growth temperature (room temperature).

A TFT manufactured with a channel length of 0.1 mm and a channel width of 2 mm had equivalent characteristics as those of the TFT manufactured according to the second example. Within a range of 5 nm or more in the film thickness of the first semiconducting layer CH1 and a range of 5 to 50 nm in the film thickness of the second semiconducting layer CH2, a threshold voltage within ±1 V, a field-effect mobility in a range from 43 to 50 cm²/Vs and an ON-state current of 2×10⁻⁴ A were obtained. Since changes in characteristics relative to film-thickness variations hardly occurred, it is possible to easily manufacture a TFT array on a large area substrate.

### Sixth Example

FIGS. 10A to 10C are diagrams illustrating a structure and a manufacturing method of a semiconductor device in accordance with a sixth example. As the semiconductor device, a so-called top-gate/top-contact type oxide TFT is used. The “top-gate” mentioned here refers to a structure in which a gate electrode GE is formed on a layer upper than a semiconducting layer CH, and the “top-contact” refers to a structure in which a source-drain electrode SD is formed on a layer upper than the semiconducting layer CH. Except for the manufacturing method, the same materials and processes as those of the second example were used.

The manufacturing method of the semiconductor device according to the present sixth example is as follows. First, as shown in FIG. 10A, on an insulator substrate SU, a second semiconducting layer CH2, a source-drain electrode SD and a first semiconducting layer CH1 are first formed. At this time, with respect to the order of forming the source-drain electrode SD and the first semiconducting layer CH1, either may be carried out first, with the other being carried out secondly.

The second semiconducting layer CH2 is formed of an oxide, such as Zn—Sn—O, Zn—O and Sn—O, and its film-forming process is carried out by a sputtering method, a PLD method, a CVD method, an application method, a printing process, etc. The film is processed by using a combination of a general-use photolithography technique and dry etching or wet etching. In the present example, as the second semiconducting layer CH2, Zn—Sn—O (Zn:Sn=30:70) was formed with a film thickness of 5 to 75 nm, by a sputtering method carried out under the conditions of a gas pressure of 0.5 Pa (Ar+20% O₂), an RF power of 50 W and a growth temperature (room temperature).

After the film formation, the source-drain electrode SD is processed by using a combination of a general-use photolithography technique and dry etching or wet etching.

The first semiconducting layer CH1 is made from an oxide, such as In—O, In—Zn—O, In—Sn—O, In—Ga—O and In—Si—O, and a composite oxide thereof, and its film-forming process is carried out by a sputtering method, a PLD method, a CVD method, an application method, a printing process, etc. The film is processed by using a combination of a general-use photolithography technique and dry etching or wet etching. In the present example, as the first semiconducting layer CH1, In—Ga—O (In:Ga=95:5) is formed with a film thickness of 3 to 60 nm, by a sputtering method carried out under the conditions of a gas pressure of 0.5 Pa (Ar+10% O₂), a DC power of 50 W and a growth temperature (room temperature).

Thereafter, as shown in FIG. 10B, after the formation of the gate insulating film GI, the film is processed by using a combination of a general-use photolithography technique and dry etching or wet etching.

Thereafter, as shown in FIG. 10C, after the formation of the gate electrode GE, the film is processed by using a combination of a general-use photolithography technique and dry etching or wet etching.

A TFT manufactured with a channel length of 0.1 mm and a channel width 2 mm had the same characteristics as those of the TFT manufactured in second example. Within a range of 5 nm or more in the film thickness of the first semiconducting layer CH1 and a range of 5 to 50 nm in the film thickness of the second semiconducting layer CH2, a threshold voltage within ±1 V, a field-effect mobility in a range from 42 to 48 cm²/Vs and an ON-state current of 2×10⁻⁴ A were obtained. Since changes in characteristics relative to film-thickness variations hardly occurred, it is possible to easily manufacture a TFT array on a large area substrate.

### Seventh Example

FIGS. 11A to 11C are diagrams illustrating a structure and a manufacturing method of a semiconductor device in accordance with a seventh example. As the semiconductor device, a so-called top-gate/bottom-contact type oxide TFT is used. The “top-gate” mentioned here refers to a structure in which a gate electrode GE is formed on a layer upper than a semiconducting layer CH, and the “bottom-contact” refers to a structure in which a source-drain electrode SD is formed on a layer lower than the semiconducting layer CH. Except for the manufacturing method, the same materials and processes as those of the second example were used.

A manufacturing method of the semiconductor device in the present seventh example is as follows. First, as shown in FIG. 11A, a source-drain electrode SD, a second semiconducting layer CH2, a first semiconducting layer CH1 are formed on an insulator substrate SU in this order.

After the film formation, the source-drain electrode SD is processed by using a combination of a general-use photolithography technique and dry etching or wet etching.

The second semiconducting layer CH2 is made from an oxide, such as Zn—Sn—O, Zn—O and Sn—O, and its film-forming process is carried out by a sputtering method, a PLD method, a CVD method, an application method, a printing process, etc. The film is processed by using a combination of a general-use photolithography technique and dry etching or wet etching. In the present example, as the second semiconducting layer CH2, Zn—O (zinc oxide: 100%) was formed with a film thickness of 5 to 75 nm, by a sputtering method carried out under the conditions of a gas pressure of 0.5 Pa (Ar+20% O₂), an RF power of 50 W and a growth temperature (room temperature).

The first semiconducting layer CH1 is made from an oxide, such as In—O, In—Zn—O, In—Sn—O, In—Ga—O and In—Si—O, and a composite oxide thereof, and its film-forming process is carried out by a sputtering method, a PLD method, a CVD method, an application method, a printing process, etc. The film is processed by using a combination of a general-use photolithography technique and dry etching or wet etching. In the present example, as the first semiconducting layer CH1, In—Si—O (In:Si=95:5) is formed with a film thickness of 3 to 60 nm, by a sputtering method carried out under the conditions of a gas pressure of 0.5 Pa (Ar+10% O₂), a DC power of 50 W and a growth temperature (room temperature).

Thereafter, as shown in FIG. 11B, after the formation of the gate insulating film GI, the film is processed by using a combination of a general-use photolithography technique and dry etching or wet etching.

Thereafter, as shown in FIG. 11C, after the formation of the gate electrode GE, the film is processed by using a combination of a general-use photolithography technique and dry etching or wet etching.

A TFT manufactured with a channel length of 0.1 mm and a channel width of 2 mm had the same characteristics as those of the TFT manufactured according to the second example. Within a range of 5 nm or more in the film thickness of the first semiconducting layer CH1 and a range of 5 to 50 nm in the film thickness of the second semiconducting layer CH2, a threshold voltage within ±1 V, a field-effect mobility in a range from 43 to 47 cm²/Vs and an ON-state current of 2×10⁻⁴ A were obtained. Since changes in characteristics relative to film-thickness variations hardly occurred, it is possible to easily manufacture a TFT array on a large area substrate.

### Comparative Example 3

A comparative example 3 only differs from the examples 1 to 7 in that, in constituent elements other than oxygen in the first semiconducting layer, the compounding ratio of In element is less than 50%, and the other points are the same as those of examples 1 to 7.

The structure and manufacturing method of the semiconductor device according to the comparative example 3 are the same as those of the seventh example (FIGS. 11A to 11C).

The manufacturing method of the semiconductor device is explained below. First, as shown in FIG. 11A, a source-drain electrode SD, a second semiconducting layer CH2 and a first semiconducting layer CH1 are formed on an insulator substrate SU in this order.

After the film formation, the source-drain electrode SD is processed by using a combination of a general-use photolithography technique and dry etching or wet etching.

The second semiconducting layer CH2 is formed of an oxide, such as Zn—Sn—O, Zn—O and Sn—O, and its film-forming process is carried out by a sputtering method, a PLD method, a CVD method, an application method, a printing process, etc. The film is processed by using a combination of a general-use photolithography technique and dry etching or wet etching. In the present example, as the second semiconducting layer CH2, Zn—Sn—O (Zn:Sn=50:50) is formed with a film thickness of 5 to 75 nm, by a sputtering method carried out under the conditions of a gas pressure of 0.5 Pa (Ar+20% O₂), an RF power of 50 W and a growth temperature (room temperature).

The first semiconducting layer CH1 is made from an oxide, such as In—O, In—Zn—O, In—Sn—O, In—Ga—O and In—Si—O, and a composite oxide thereof, and its film-forming process is carried out by a sputtering method, a PLD method, a CVD method, an application method, a printing process, etc. The film is processed by using a combination of a general-use photolithography technique and dry etching or wet etching. In the present example, as the first semiconducting layer CH1, In—Si—O (In:Si=40:60) is formed with a film thickness of 3 to 60 nm, by a sputtering method carried out under the conditions of a gas pressure of 0.5 Pa (Ar+10% O₂), a DC power of 50 W and a growth temperature (room temperature).

Thereafter, as shown in FIG. 11B, after the formation of the gate insulating film GI, the film is processed by using a combination of a general-use photolithography technique and dry etching or wet etching.

Thereafter, as shown in FIG. 11C, after the formation of the gate electrode GE, the film is processed by using a combination of a general-use photolithography technique and dry etching or wet etching.

In the TFT manufactured and compared with the TFT manufactured according to the examples 2 to 7, as the film thickness of the first semiconducting layer CH1 increased, the threshold voltage was shifted so that a field-effect mobility of about 15 to 20 cm²/Vs was exerted. When the compounding ratio of In element became less than 50% in the constituent elements other than oxygen in the first semiconducting layer CH1, the TFT characteristics drastically deteriorated. The reason for this result is presumably because the carriers were reduced due to the reduction of In concentration inside the first semiconducting layer CH1.

### Eighth Example

FIG. 12 is a view illustrating a structure of a semiconductor device in accordance with the present eighth example. By using a TFT having a structure shown in each of examples 2 to 7, an antenna resonance circuit 11, a rectifier 12, a modulator 13, a digital circuit 14 and the like are constructed whereby a wireless tag is formed. The wireless tag is designed such that radio communication can be performed with a reader 15 or a writer 16. Moreover, since the oxide semiconductor is a transparent material, a virtually transparent circuit can be formed. For example, electrodes and wiring portions are formed by using transparent conductive films such as ITO, etc., while the structure of the present invention is used as TFT portions so that such a circuit could be achieved, and transmitting and receiving operations at 13.56 MHz were confirmed. Being different from the conventional radiofrequency identification (RFID) tag, since the resultant mode does not allow the structure such as an antenna or the like formed of Si chips and metal to be seen, the tag can be post-added thereto, without impairing a design or the like put on a film, a card or the like.

### Ninth Example

FIG. 13 is a diagram illustrating a structure of a semiconductor device in accordance with a ninth example. In the present ninth example, elements, each having a TFT having a structure described in each of the examples 2 to 7 as its constituent element, are arranged in an array form on a substrate SU. Of course, the TFT shown in each of the examples 2 to 7 may be used as a transistor for switching and driving each of the elements inside the array, or may also be used as a transistor for a gate-line driving circuit 18 for sending signals to a gate wiring 17 to be connected to a gate electrode GE of this TFT or as a transistor forming a data-line driving circuit 20 for sending signals to a data wiring 19 to be connected to the source electrode-drain electrode SD of this TFT. In this case, the TFTs of the respective elements and the TFTs inside the gate-line driving circuit 18 or the data-line driving circuit 20 can be formed in parallel with each other.

When the above-mentioned array is applied to an active-matrix-type liquid crystal display device, each element is formed in a configuration as shown in, for example, FIG. 14. When a scanning signal is supplied to the gate wiring 17 that is extended and located in an x-direction in the diagram, a TFT 21 is turned on, and through this on-state TFT 21, a video signal from the data wiring 19 extended and located in a y-direction in the diagram is supplied to a pixel electrode 22. Additionally, the gate wirings 17 are arranged side by side in the y-direction in the diagram, and the data wirings 19 are arranged side by side in the x-direction in the diagram, whereby a pixel electrode 22 is placed in an area (pixel area) surrounded by paired adjacent gate wirings 17 and paired adjacent data wirings 19. In this case, for example, the data wiring 19 may be electrically connected to the source electrode SE, and the pixel electrode 22 is electrically connected to the drain electrode DE. Alternatively, the data wiring 19 may be compatibly used as the source electrode SE. Moreover, not limited to the liquid crystal display device, the above-mentioned array may be applied to an organic EL display device, etc. In this case, the TFT is applied to each of the transistors forming the pixel circuit. Moreover, the above-mentioned array may be used in a memory device, and the TFT may be used in a selection transistor.

In the foregoing, the invention made by the inventors of the present invention has been concretely described based on the embodiments. However, it is needless to say that the present invention is not limited to the foregoing embodiments and various modifications and alterations can be made within the scope of the present invention.

### INDUSTRIAL APPLICABILITY

The present invention relates to an oxide semiconductor device, and can be applied to a semiconductor device containing a field-effect transistor in which an oxide film is used as a channel.

### DESCRIPTIONS OF REFERENCES

SU . . . Substrate, GE . . . Gate electrode, GI . . . Gate insulating film, CH1 . . . First semiconducting layer, CH2 . . . Second semiconducting layer, tc1 . . . Film thickness of first semiconducting layer, tc2 . . . Film thickness of second semiconducting layer, SE . . . Source electrode, DE . . . Drain electrode, VS . . . Source voltage, VD . . . Drain voltage, VG . . . Gage voltage, SD . . . Source-drain electrode, wiring, CH . . . Semiconducting layer, Rc . . . Resistance value of channel layer, Rc1 . . . Resistance value of first semiconducting layer between channel layer and source-drain electrode, Rc2 . . . Resistance value of second semiconducting layer between channel layer and source-drain electrode, CON . . . Wiring contact hole, BL . . . Barrier layer, 11 . . . Antenna resonance circuit, 12 . . . Rectifier, 13 . . . Modulator, 14 . . . Digital circuit, 15 . . . Reader, 16 . . . Writer, 17 . . . Gate wiring, 18 . . . Gate line driving circuit, 19 . . . Data wiring, 20 . . . Data wiring driving circuit, 21 . . . Thin film transistor, 22 . . . Pixel electrode

1. A field-effect transistor comprising:
a gate electrode;
a first semiconducting layer provided on the gate electrode interposing a gate insulating film;
a second semiconducting layer connected to the first semiconducting layer;
a source electrode connected to the second semiconducting layer; and
a drain electrode connected to the second semiconducting layer,
wherein the first semiconducting layer contains In (indium) element and O (oxide) element, and
the second semiconducting layer contains Zn (zinc) element and O element and does not contain In element.

2. The field-effect transistor according to claim 1,
wherein the first semiconducting layer further contains Zn element, Sn (tin) element, Ge (germanium) element or Si (silicon) element.

3. The field-effect transistor according to claim 1,
wherein the second semiconducting layer further contains Sn (tin) element.

4. The field-effect transistor according to claim 1,
wherein the first semiconducting layer and the source electrode are not directly connected to each other.

5. The field-effect transistor according to claim 1,
wherein the source electrode is directly connected to the first semiconducting layer and the second semiconducting layer, and,
when taking a resistance value of a portion through the first semiconducting layer in a resistance between a channel layer of the first semiconducting layer and the source electrode as R1, and taking a resistance value of a portion through the second semiconducting layer in a resistance between the channel layer and the source electrode as R2, R1 is greater than R2.

6. The field-effect transistor according to claim 1,
wherein the first semiconducting layer is designed such that in constituent elements other than oxygen relative to the entire elements, the compounding ratio of In element is 50% or more.

7. The field-effect transistor according to claim 1,
wherein the gate electrode is provided on a substrate of the field-effect transistor,
the gate insulating film is provided on the gate insulating film,
the first semiconducting layer is provided on the gate insulating film,
the second semiconducting layer is provided on the first semiconducting layer, and
the source electrode and the drain electrode are provided on the second semiconducting layer.

8. A method of manufacturing a field-effect transistor comprising:
a first step of forming a first semiconducting layer containing In (indium) element and O (oxide) element on a gate insulating film; and
a second step of forming a second semiconducting layer containing Zn (zinc) element and O element and not containing In element on the first semiconducting film.

9. The method of manufacturing a field-effect transistor according to claim 8,
wherein, after carrying out the first step, a third step of removing the first semiconducting layer except for a predetermined portion is further carried out, and the second step is carried out thereafter.

10. The method of manufacturing a field-effect transistor according to claim 9,
wherein, after carrying out the second step, a fourth step of removing the second semiconducting layer except for a predetermined portion is further carried out.

11. The method of manufacturing a field-effect transistor according to claim 10,
wherein, after carrying out the fourth step, a fifth step of forming a source electrode to be connected to the second semiconducting layer and a drain electrode to be connected to the second semiconducting layer is further carried out.

12. The method of manufacturing a field-effect transistor according to claim 8,
wherein, after carrying out the first step, the second step is carried out, and,
after carrying out the second step, a sixth step of removing the first semiconducting layer and the second semiconducting layer except for predetermined portions is further carried out.

13. The method of manufacturing a field-effect transistor according to claim 12,
wherein, after carrying out the sixth step, a seventh step of forming a source electrode to be connected to the first semiconducting layer and the second semiconducting layer as well as a drain electrode to be connected to the first semiconducting layer and the second semiconducting layer is further carried out.

14. The method of manufacturing a field-effect transistor according to claim 8,
wherein the first semiconducting layer further contains Zn element, Sn (tin) element, Ge (germanium) element or Si (silicon) element.

15. The method of manufacturing a field-effect transistor according to claim 8,
wherein the second semiconducting layer further contains Sn element.
